(19) United States
(12) Patent Application Publication
(10) Pub. No.: US 2008/0241523 A1
(43) Pub. Date: Oct. 2, 2008

(54) Substrate, Such As A Glass Substrate, With A Hydrophobic Surface And Improved Durability Of Hydrophobic Properties

(75) Inventors: Arnaud Huignard, Paris (FR); Maxime Duran, Cavanac (FR)

Correspondence Address: OBLON, SPIVAK, MCCLELLAND MAIER & NEUSTADT, P.C., 1940 DUKE STREET, ALEXANDRIA, VA, 22314, US

(73) Assignee: SAINT-GOBAIN GLASS FRANCE, Courbevoie (FR)

(21) Appl. No.: 10/590,197

(22) PCT Filed: Feb. 23, 2005
(86) PCT No.: PCT/FR05/50119

§ 371 Date: Nov. 27, 2007

(30) Foreign Application Priority Data
Feb. 24, 2004 (FR) 0450343

(51) Int. Cl. B32B 33/00; B32B 9/04; C23C 16/513; B05D 1/02; C23C 4/04; B32B 9/00

(52) U.S. Cl. 428/336; 428/446; 428/428; 428/450; 427/578; 427/452; 427/427; 428/447; 428/340; 428/409

(57) ABSTRACT

The invention relates to a substrate of which at least one part of the surface thereof has been rendered hydrophobic and, for said purpose, has a hydrophobic surface structure consisting of an essentially-mineral silicon-containing sub-layer and an outer layer comprising a hydrophobic agent which is grafted onto said sub-layer. The invention is characterised in that the outer hydrophobic agent layer is applied to the sub-layer while the surface of the latter is in an activated state before being brought into contact with said hydrophobic agent. The invention also relates to rain-repellent glass comprising one such substrate, which is particularly suitable for use in the automobile, aviation, construction, electric household appliance and ophthalmic lens industries.

The present invention relates to a substrate, especially a glass substrate, the surface of which has been rendered hydrophobic, with improved durability of the hydrophobic properties.

Hydrophobic properties are sought for windows and windshields in the transport field, in particular for motor vehicles and aircraft, and also for glazing in the building industry.

For applications in the transport field, rain-repellent properties are sought, the water droplets on windshields thus having to easily roll off the glass wall so as to be removed, for example when the vehicle is in motion due to the effect of the air or wind, and to do so with the purpose of improving visibility and, consequently safety, or for facilitating cleaning, or for easily defrosting, etc.

For applications in the building field, the aim is essentially to make cleaning easier.

For this purpose, the aim is to have an angle of contact of a water droplet with the substrate that is greater than 60° or 70°, the water droplet having not to be flattened or spread out. This is because glazing is said to be functional as long as this angle is greater than 60° in the case of aircraft, and greater than 70° in the case of automobiles. However, in practice this angle should in all cases exceed 90°, the ideal being to obtain droplets that roll off, allowing the water to be removed so quickly as to be able to dispense as far as possible with windshield wipers in the automotive field.

Moreover, the improvement in hydrophobic properties thus sought must not be to the detriment of the preservation of the other properties, such as resistance to mechanical stresses: resistance to shear friction (standardized Opel test, carried out dry), abrasion resistance (Taber test), resistance to wiping by wipers (test simulating the cycles of wiper action); resistance to environmental stresses (WOM test of UVA resistance, or Xenon test; QUV test of UVB resistance for aircraft; NSS (neutral salt spray) resistance test; resistance to chemical stresses: test of resistance to acid and basic detergents; and the optical properties.

To render a glass hydrophobic it is known to coat it with a dense silica mineral layer serving as primer for the grafting of molecules having hydrophobic properties, such as fluorosilane molecules. Thus, European patent EP 0 545 201 describes the application of a dense SiO₂ layer applied by magnetron sputtering, said SiO₂ layer being subsequently coated with a hydrophobic agent.

The filing company has discovered that the hydrophobic properties of such a structure can be further improved, in particular in their durability, with the other properties mentioned above being at least maintained, or even sometimes improved, if the coating of molecules having hydrophobic properties is applied while this layer is in an activated surface state, this activation being able to be produced either by the actual conditions under which the mineral layer is deposited, or by a specific activation treatment.

Thus, the mineral layer (which is the sublayer in the resulting final structure) may be deposited by vacuum sputtering, especially magnetron sputtering, under conditions that allow the layer to be left in an unstable surface state, with the hydrophobic coating being applied while the surface is still in this state (generally applied immediately), or by a specific activation treatment (plasma excitation, etc.).

A first subject of the present invention is therefore a substrate, at least one part of the surface of which has been rendered hydrophobic, having for this purpose a hydrophobic surface structure comprising an essentially mineral silicon-containing sublayer and an outer layer of hydrophobic agent grafted onto said sublayer, characterized in that said sublayer has received the outer layer of hydrophobic agent although it had a surface that was in an activated state before being brought into contact with said hydrophobic agent.

The term “activated” is understood to mean that said surface has undergone a treatment which has modified its electrostatic state (by production of charges) and/or its chemical state (creation or destruction of chemical functional groups), in order to increase the reactivity of said surface, which treatment may go as far as tearing the material of the surface, thus creating irregularities. Moreover, as will be indicated below, the layer of silicon-containing mineral material that will constitute the sublayer in the final structure may be obtained under conditions in which it is directly in the activated state.

The sublayer may be a hard sublayer.

The substrate is especially formed by, or comprises in its part intended to bear said mineral sublayer, a plate, whether plane or with curved faces, of monolithic or laminated glass, of glass-ceramic or of a hard thermoplastic, such as polycarbonate. The glass may be a toughened glass. An example of a curved plate is a windshield. This may be in the assembled state.

The sublayer of the hydrophobic coating may form part of the substrate, the latter being formed by a plate, whether plane or with curved faces, of monolithic or laminated glass or of glass-ceramic, the composition of which, at least on the surface, corresponds to that of the essentially mineral silicon-containing sublayer. An example of a substrate having such an integrated sublayer is a glass dealkylized at least on its surface. International applications WO-94/07806 and WO-94/07807 describe this technology.

The silicon-containing sublayer is especially formed by a compound chosen from SiOₓ, where x≦2, SiOC, SiON, SiOCN and Si₃N₄, it being possible for hydrogen to be combined in all proportions with SiOₓ, where x≦2, SiOC, SiON and SiOCN. It may also contain aluminum, in particular up to 8% by weight, or carbon, Ti, Zr, Zn and B.

Mention may also be made of sublayers consisting of scratch-resistant lacquers, such as polysiloxanes, which have been applied as coating on polycarbonate substrates.

The silicon-containing sublayer when its surface is in the activated state has a thickness of between 20 nm and 250 nm, especially between 30 nm and 100 nm and in particular between 30 nm and 75 nm. It may have an RMS roughness of between 0.1 nm and 40 nm, in particular between a few nm and 30 nm. It may have an actual developed area at least 40% greater than the initial plane area. Under an SEM microscope, said sublayer may have the appearance of pumistone or of islands.

Moreover, the silicon-containing sublayer when its surface is in the activated state advantageously has a hardness such that it does not delaminate after 100 revolutions, and preferably up to 200 revolutions, in the Taber test.

The hydrophobic agent may be chosen from:
(a) alkylsilanes of formula (I):

CH₃(CH₂)ₙSiRₘX₃₋ₘ (I)

in which:
n ranges from 0 to 30, more particularly from 0 to 18;
m=0, 1, 2 or 3;
R represents an optionally functionalized organic chain; and
X represents a hydrolyzable residue, such as an OR⁰ residue, where R⁰ represents hydrogen; or a linear, branched or cyclic, especially C₁-C₈, alkyl residue; or an aryl residue; or such as a halo, for example chloro, residue;
(b) compounds with grafted silicone chains, such as for example (CH₃)₃SiO [Si(CH₃)₂O]_{q}, with no specific limitation as regards the chain length (value of q) and the method of grafting;
(c) fluorosilanes, such as those of formula (II):

R¹-A-SiRₚ²X₃₋ₚ (II)

in which:
R¹ represents an especially C₁-C₉ monofluoroalkyl, oligofluoroalkyl or perfluoroalkyl residue; or a monoaryl, oligoaryl or perfluoroaryl residue;
A represents a hydrocarbon chain, optionally interrupted by a heteroatom such as O or S;
R² represents a linear, branched or cyclic, especially C₁-C₈, alkyl residue, or an aryl residue;
X represents a hydrolyzable residue, such as an OR³ residue, where R³ represents hydrogen or a linear, branched or cyclic, especially C₁-C₈, alkyl residue; or an aryl residue; or such as a halo, for example chloro, residue; and
p=0, 1 or 2.

An example of an alkylsilane of formula (I) is octadecyltrichlorosilane (OTS).

The preferred hydrophobic agents are fluorosilanes (c), in particular those of formula (II), particular examples of the latter being those of formula:

CF₃—(CF₂)ₙ—(CH₂)₂—Si(R⁴)₃

in which:
R⁴ represents a lower alkyl residue; and
n is between 7 and 11.

The layer of hydrophobic agent has for example a thickness of between 1 and 100 nm, preferably between 2 and 50 nm.

The layer of fluorosilane may have a weight per unit area of grafted fluorine of between 0.1 μg/cm² and 3.5 μg/cm², in particular between 0.2 μg/cm² and 3 μg/cm².

The subject of the present invention is also a process for manufacturing a substrate as defined above, characterized in that a coating layer of hydrophobic agent is deposited, in at least one pass, on the surface of a silicon-containing mineral layer formed at least partly on the surface of the substrate, said deposition of the hydrophobic agent taking place while said surface is in the activated state.

An activated surface of the silicon-containing mineral layer may be obtained by depositing it under conditions in which its surface is obtained directly in the activated state. This is what occurs if a silicon-containing layer is deposited, cold, by PECVD (plasma enhanced chemical vapor deposition) or by magnetron and/or ion-beam sputtering.

This is because, in such processes, the growth of the layer takes place using reactive species (ions, radicals, neutrals, etc.) which combine to form the coating. The surface of the coating is therefore by nature in an off-equilibrium state. In addition, this layer may be directly in contact with the plasma gas during growth, which will further increase the activity of the surface and its reactivity (as in the PECVD process).

It is also possible to obtain an activated surface of the silicon-containing mineral layer by carrying out an activation treatment in at least one pass.

Advantageously, the hydrophobic agent is deposited within the shortest possible time, preferably between 1 second and 15 minutes, after the activated surface has been obtained.

An activation treatment may be carried out under conditions that do not go as far as etching, by the use of a plasma or an ionized gas, at reduced or atmospheric pressure, chosen from air, oxygen, nitrogen, argon, hydrogen, ammonia and mixtures thereof, or by the use of an ion beam.

It is also possible to carry out an activation treatment under conditions that allow a silicon-containing layer to be etched, by the use of a plasma of at least one fluorine-containing gas chosen from SF₆, CF₄, C₂F₆ and other fluorinated gases, where appropriate combined with oxygen, it being possible for the oxygen to represent up to 50% by volume of the etching plasma.

Moreover, according to the present invention, the activation carried out under conditions that allow the silicon-containing layer to be etched by an activation treatment, which does not cause additional etching but does still modify the chemical nature and/or the electrostatic state of said layer, may be monitored.

The silicon-containing layer may be deposited, cold, on the substrate by vacuum cathode sputtering, preferably magnetron sputtering and/or ion beam sputtering, or by low-pressure or atmospheric-pressure PECVD, or else deposited hot by pyrolysis.

As examples of the deposition of the SiO₂ sublayer, the following method of implementation may be mentioned, in which: a layer of SiO₂ is deposited on bare glass or on an assembled windshield by PECVD, using a mixture of an organic or nonorganic, silicon-containing precursor, such as SiH₄, hexamethyldisiloxane (HMDSO), tetraethoxysilane (TEOS) and 1,1,3,3-tetramethyldisiloxane (TMDSO), and an oxidizer (O₂, NO₂, CO₂), the subsequent activation being carried out in the same chamber or in a separate chamber.

The hydrophobic agent layer may be deposited by wiping-on, evaporation or spraying of a solution containing the hydrophobic agent, or by dipping, spin-coating, flow-coating, etc., using a solution containing the hydrophobic agent.

To manufacture glazing with a hydrophobic coating according to the present invention, it will be possible to use inter alia, one of the following three general methods:
(1) the sublayer is deposited on the glass on a glass manufacturing line using the “float” process while the glass is being supported by the bath of molten tin, or in a subsequent step, that is to say on leaving the bath of molten tin, the conversion operations are then carried out, such as bending, toughening and/or assembling, especially by lamination, in order to obtain plates of glass made up from one or more sheets coated with the sublayer on at least one face, the sublayer or sublayers supported by said plates are then activated and, finally, a functionalization by the hydrophobic agent of the sublayer or sublayers thus activated is carried out. The sublayer is generally deposited by PECVD or magnetron sputtering;
(2) sheets of glass are manufactured by the float process, said glass sheets are then converted by operations such as bending, toughening and/or assembling, especially lamination, in order to obtain plates of glass made up from one or more sheets, the sublayer is then deposited on at least one face of the plates thus obtained, and the sublayer or sublayers are then activated, followed by the functionalization by the hydrophobic agent of the sublayer or sublayers thus activated;
(3) the sublayer is deposited on at least one face of glass sheets obtained upon leaving the float process, these sheets thus coated with the sublayer or sublayers are converted, limiting the techniques used to those that do not damage said sublayer(s) (thereby excluding bending and toughening as conversion operations, but allowing assembling, especially by lamination), and the sublayer or sublayers are then activated, followed by the functionalization by the hydrophobic agent of said sublayer or sublayers thus activated.

The present invention also relates to rain-repellent glazing comprising a substrate as defined above or prepared by the process as defined above. Mention may be made of glazing for buildings, including glazing for shower cubicles, glass for electrical household appliances, especially glass-ceramic hobs, glazing for transport vehicles, especially for automobiles and aircraft, in particular for windshields, side windows, rear windows, wing mirrors, sunroofs, headlamp and rear light optics, and ophthalmic lenses.

The following examples illustrate the present invention without however limiting the scope thereof. In these examples, the following abbreviations have been used:
PECVD: plasma enhanced chemical vapor deposition;
SEM: scanning electron microscopy;
AFM: atomic force microscopy; and
AWR: aviation wiping rig.

### EXAMPLE 1

### Substrate Having a Hydrophobic Surface According to the Invention with a Silica Sublayer Formed by PECVD

(a) Formation and Characterization of the Hard Silica Sublayer

A thin silica (SiO₂) layer was deposited on a clean glass (measuring 300×300 mm²) in a low-pressure PECVD reactor. Before each experiment, the residual vacuum reached in the chamber was at least 5 mPa (5×10⁻⁵ mbar). The gas mixture was then introduced into the chamber. The gases used were pure silane (SiH₄), nitrous oxide (N₂O) and dilution helium, the respective flow rates of which were 18 sccm, 60 sccm and 60 sccm. The total pressure in the reactor was then set at 9.99 Pa (75 mTorr). In equilibrium, the plasma was struck by biasing the gas diffuser with an average radiofrequency (13.56 MHz) power of 190 W (bias voltage: ˜45 V). The temperature of the substrate was kept at 25° C. The thickness of silica thus deposited after 270 s was about 50 nm.

The surface state of the PECVD silica observed in SEM was characterized by small grains about twenty nanometers in size, which, in places, formed circular or elongate areas of additional thickness that were hollow at their center.

The hardness of the silica obtained was characterized using the following two tests:
firstly, the layer underwent an abrasion treatment, during which the haze was measured according to the standard ISO 3537; the abrasion was of the Taber type, carried out by means of a CS10F abrasive wheel with an applied force of 4.9 N (500 g). The degree of abrasion was denoted by the number of Taber revolutions. The measured haze values are given in Table 1 below; and
secondly, the hardness of the silica was assessed by the Airco rating, the value being 10-0.18R in which R is the number of scratches, after a given number of Taber revolutions, in a frame measuring 2.54 cm×2.54 cm, visible on a photograph with a ×50 magnification. The Airco ratings are also given in Table 1 below.

TABLE 1
Characterization of the SiO₂ sublayer

| | |
|---|---|
| State of | Taber revolutions |

| abrasion: | 50 | 100 | 200 | 300 |
|---|---|---|---|---|
| Haze | 0.55 | 1.01 | 1.58 | 1.75 |
| Airco | 7.48 | 7.48 | 6.76 | 5.86 |

These values characterize a hard SiO₂ layer.

(b) Plasma Treatment

The SiO₂ layer was then subjected to a plasma treatment.

As in the case of the deposition experiments, a residual vacuum of at least 5 mPa (5×10⁻⁵ mbar) was again created in the chamber before the reactive gas mixture was introduced. The gases used for the surface treatment of the silica were C₂F₆ and oxygen, the respective flow rates of which were 120 sccm and 20 sccm. The total pressure in the reactor was then set at 26.66 Pa (200 mTorr). At the equilibrium, the plasma was struck by biasing the gas diffuser with an average radiofrequency (13.56 MHz) power of 200 W (bias voltage: ˜15 V) for a time of 900 s at room temperature.

After 15 minutes of C₂F₆/O₂ plasma treatment, the silica layer was highly etched. Its surface had large blisters a few tens of nanometers in size. The microroughness obtained with this highly aggressive plasma (etching) treatment was characterized by AFM, indicating an apparent roughness on the scale of the fluorosilane molecules subsequently grafted onto the silica.

The main microroughness parameters of the PECVD silica measured by AFM are given in Table 2 below.

TABLE 2

| | | | Developed | |
|---|---|---|---|---|
| | ΔZₘₐₓ* | Rᵣₘₛ | area | Increase |
| Substrate | (nm) | (nm) | (2 × 2 μm²) | (%) |
| Flat | 0.5 | ~0.2 | 4.1 | +2.5 |
| glass | | | | |
| SiO₂ | 10 | 1.657-2.116 | 4.431 | +10.785 |
| Etched | 30 | 5.981-7.216 | 5.5 | +37 |
| SiO₂ | | | | |

*ΔZₘₐₓ is the maximum peak/valley amplitude.

(c) Application of Fluorosilane

After the surface of the PECVD silica had been plasma-treated, a composition was wiped onto the specimens, the composition having been produced 12 hours beforehand in the following manner (the percentages are in weight):
90% of propanol-2 and 10% of 0.3N HCl were mixed in water; and
added to the two aforementioned constituents was 2% of the compound of formula C₈F₁₇(CH₂)₂Si(OEt)₃ (Et=ethyl).

The weights per unit area of fluorine grafted onto the surface of the various sublayers, determined by electron microprobe, were:

| | |
|---|---|
| on flat glass (with sol-gel | 0.15 μg/cm² |
| SiO₂ primer sublayer): | |
| on SiO₂ (PECVD): | 0.369 μg/cm² |
| on etched SiO₂ (PECVD): | 1.609 μg/cm². |

The amount of fluorine grafted onto the etched SiO₂ sublayer is remarkably high.

(d) Characterization of the Hydrophobic Substrate Obtained

The characteristics of the hydrophobic substrate obtained were:
droplet contact angle: μ_{water}≧105°;
optical properties: T_{L}=90.2%; R_{L}=8.44%; absorption=1.36%; haze=0.2%;
detachment volumes: 13 μl at 90° and 22 μl at 45° (the angles being the angles of inclination of the substrate to the horizontal).

Next, the above three types of fluorosilane-grafted substrates were subjected to two types of mechanical tests:
Taber test using a CS-10F abrasive wheel with a load of 4.9 N (500 g);
Opel test according to Building Standard EN 1096-2 of January 2001, consisting in applying, to part of the coated surface 9.4 cm in length—this part being called a track—a felt 14 mm in diameter, 10 mm in thickness and 0.52 g/cm² in density, and a load of 39.22 MPa (400 g/cm²), the felt being subjected to a translational movement (50 to-and-fro movements over the entire track length per minute) combined with a rotation of 6 revolutions/minute (1 cycle=1 to-and-fro movement).

The results of the Opel and Taber tests on the etched and unetched PECVD layers compared with the flat glass are given in Table 3 below.

TABLE 3

| | |
|---|---|
| Opel (39.22 MPa | Taber revolutions |
| (0.4 kg/cm²)) | (CS-10F-4.9 N (500 g)) |

| | 5000 cycles | 100 | 300 |
|---|---|---|---|
| Control* | 95° ± 5° | 75° ± 5° | ≦60° |
| PECVD SiO₂ | 87° ± 2° | 95° ± 1° | 83° ± 2° |
| Etched SiO₂ | 95° ± 5° | 90° ± 1° | 74° ± 2° |

*Specimen prepared according to Example 5b of EP 799 873 B1.

The 87° value in the Opel test (5000 cycles) for the case of the SiO₂ sublayer is not sufficient.

Only the substrate with an etched SiO₂ sublayer results in a good compromise between the Opel test and the Taber test (100 revolutions).

This substrate was therefore tested in the AWR, consisting in moving an aircraft windshield wiper over it along a 25 cm track in a transverse movement consisting of two to-and-fro movements per second, under a load of 0.88 N/cm (90 g/cm) with a water spray of 6 l/h.

A mean angle of about 80°±10° after 1 000 000 cycles was measured, with only 26% of the area not functional (μ_{water}<60°). The functionality limit was measured to be 1 400 000 cycles, at which the mean angle was about 70°±10° with more than 35% of the area not functional.

The substrate was also assessed by the following main accelerated environmental tests:
WOM or Xenon test: 0.55 W/m² irradiation at 340 nm;
QUV: 16 h of UV-B (313 nm) at 70° C.+8 h at 40° C. (>95% residual humidity);
NSS: exposure at +35° C., 50 g/l NaCl at 7 pH according to the IEC 60 068 standard, part 2-11 Ka.

All the results are given in Table 4.

TABLE 4

| | WOM | | QUV | | BSN | |
|---|---|---|---|---|---|---|
| | 600 h | 2000 h | 1500 h | 3500 h | 2 weeks | 4 weeks |
| Control* | 105° ± 5° | 95° ± 3° | 90° ± 5° | | 65° ± 15° | 65° ± 15° |
| Etched | 104° ± 5° | 102° ± 3° | 105° ± 5° | 95° ± 3° | 103° ± 15° | 103° ± 5° |
| SiO₂ | | | | | | |

*Specimen prepared according to Example 5b of EP 799 873 B1.

The etched PECVD sublayers made it possible to maintain, in the QUV test, a μ_{water}>80°±6° after 7000 hours of exposure and a μ_{water}≧96°±3° after 2800 hours of exposure in the WOM.

### EXAMPLE 2

### Substrate Having a Hydrophobic Surface According to the Invention with a Silica Sublayer Deposited by Magnetron Sputtering

(a) Formation and Characterization of the Hard Silica Layer

This example relates to the grafting of fluorosilane onto an SiO₂ sublayer formed by reduced-pressure magnetron sputtering.

Three types of SiO₂ were produced:
SiO₂ under a pressure of 200 Pa (2 μbar); Ar flow rate: 15 sccm; O₂ flow rate: 12 sccm;
SiO₂ under a pressure of 400 Pa (4 μbar); Ar flow rate: 27 sccm; O₂ flow rate: 12 sccm;
SiO₂ under a pressure of 800 Pa (8 μbar); Ar flow rate: 52 sccm; O₂ flow rate: 15 sccm.

The plasma was ignited by increasing the DC power from 0 to 2000 W at a rate of 20 W/s.

A presputtering operation consisted in applying, for 3 minutes, a 40 kHz pulsed DC power of 2000 W with 4 μs between the pulses.

A target containing 92% silicon and 8% aluminum was sputtered.

To obtain a 100 nm SiO₂ coating in one pass, the run speed of the substrate beneath the target was: 5.75 cm/min (200 Pa/2 μbar), 5.73 cm/min (400 Pa/4 μbar) and 5.53 cm/min (800 Pa/8 μbar).

The hardness of the 200 Pa (2 μbar) and 800 Pa (8 μbar) magnetron SiO₂ layers was measured as described in the case of the PECVD SiO₂ layers above: measurement of the haze (in %) during a Taber abrasion test (ISO 3537), Airco rating.

The results are given in Table 5 below.

TABLE 5

| | |
|---|---|
| Measured abrasion | Taber revolutions |

| | | | | |
|---|---|---|---|---|
| state: | 50 | 100 | 200 | 300 |

| | | | | | |
|---|---|---|---|---|---|
| Haze (%) | SiO₂—200 Pa | 0.55 | 0.86 | 1.35 | 1.48 |
| | SiO₂—800 Pa | 0.68 | 0.99 | 1.48 | 1.69 |
| Airco | SiO₂—200 Pa | 7.84 | 7.87 | 7.48 | 7.3 |
| | SiO₂—800 Pa | 8.02 | 7.84 | 7.12 | 6.94 |

These SiO₂ layers produced by magnetron sputtering were hard layers.

(b) Plasma Treatment

Magnetron-deposited (400 Pa/4 μbar and 800 Pa/8 μbar) silicas were plasma-etched (230 W/300 s) as follows:
1) SiO₂ (400 Pa/4 μbar): 30%-70% SF₆ at 9.99 Pa/75 mTorr;
2) SiO₂ (800 Pa/8 μbar): a) 20% O₂/80% C₂F₆ at 26.66 Pa/200 mTorr; b) 50% O₂/50% C₂F₆ at 26.66 Pa/200 mTorr.

(c) Fluorosilane Application

The procedure was as described at (c) of Example 1.

Five specimens were subjected to various tests, as described below:
I SiO₂ (400 Pa/4 μbar) sublayer plasma treated according to 1) above and then the fluorosilane wiped on in order to graft it (as described above);
II SiO₂ (400 Pa/4 μbar) sublayer with no plasma treatment and the fluorosilane wiped on, upon leaving the magnetron line for preparing the SiO₂;
III SiO₂ (800 Pa/8 μbar) sublayer plasma treated according to 2a) above and then the fluorosilane wiped on;
IV SiO₂ (800 Pa/8 μbar) sublayer plasma treated according to 2b) above and then the fluorosilane wiped on; and
V SiO₂ (800 Pa/8 μbar) sublayer with no plasma treatment and the fluorosilane wiped on, upon leaving the magnetron line for preparing the SiO₂.

The results are given in Table 6 below.

TABLE 6

| | | Water | | | | | | |
|---|---|---|---|---|---|---|---|---|
| | | detachment | | | | | | % |
| | | volume | | μ_{water} (°) | | | | haze |
| | Etched | (μl) | | | Opel | Taber | | 1000 |
| Spec- | thickness | at | at | | (5000 | (1000 | NSS | Taber |
| imen | (mm) | 45° | 90° | Initial | cycles) | rev.) | (3 wk.) | rev. |
| I | 25 | 24 | 14 | 109.5 | 101.6 | 92 | 108.3 | 1.09 |
| II | | | | 110.4 | 102.9 | 92.3 | | |
| III | 25 | 24 | 13 | 110.3 | 102.9 | 95 | 108.2 | |
| IV | 56 | 23 | 13 | 111.1 | 106.7 | 90.6 | 107.1 | |
| V | | | | 111 | 101.4 | 88.7 | | |

This table shows the very high performance in general, and especially that of test III in the Taber test and test IV in the Opel friction test.

### EXAMPLE 3

The purpose of this example is to compare four hydrophobic glasses:
VI specimen prepared according to Example 5b of EP 799 873 B1;
VII magnetron-deposited SiO₂ (800 Pa/8 μbar) sublayer (Example 2) plasma treated with 70 sccm of SF₆, 30 sccm O₂ at 9.99 Pa/75 mTorr, 230 W, 300 s, the fluorosilane being wiped on;
VIII magnetron-deposited SiO₂ (400 Pa/4 μbar) sublayer (Example 2) plasma treated with 50 sccm of C₂F₆, 50 sccm at 26.66 Pa/200 mTorr, 230 W, 300 s, the fluorosilane being wiped on; and
IX fluorosilane application by wiping on, upon leaving the magnetron-deposited (800 Pa/8 μbar) silica production line.

Various tests were carried out on the specimens thus formed, and the results are given in Table 7 below.

TABLE 7

| | μ_{water} (°) | | | | % |
|---|---|---|---|---|---|
| | | Taber | Opel | AWR | degraded |
| | | (100 | (5000 | (50 000 | area |
| Specimen | Initial | revs.) | cycles) | cycles) | (μ_{water} < 60°) |
| VI | 109.6 | 88.4 | 104.7 | 104.8 | 1.0 |
| VII | 111.8 | 93 | 103.5 | 105.0 | 0.0 |
| VIII | 112.5 | 101.7 | 104.8 | 96.0 | 1.5 |
| IX | 112.2 | 86 | 108.1 | 96.4 | 5.5 |

The percentage of degraded area (μ_{water}<60°) was assessed after 50 000 AWR cycles.

Specimens VI to IX that had undergone 50 000 AWR cycles were subjected to an NSS test in the case of some of them and to a QUV test in the case of the others.

The results are given in Table 8 below.

TABLE 8

| | μ_{water} (°) | | | | | | |
|---|---|---|---|---|---|---|---|
| | NSS | | | | QUV | | |
| | Number of days | | | | Number of hours | | |
| Specimen | 0 | 3 | 20 | 50 | 0 | 1431 | 3187 |
| VI | 105.8 | 64.1 | 25.0 | | 99.0 | 89.0 | 87.0 |
| VII | 106.9 | 106.6 | 105.1 | 99.4 | 96.0 | 99.0 | 87.0 |
| VIII | 99.7 | 95.7 | 89.4 | 84.8 | 92.0 | 71.0 | 61.0 |
| IX | 97.8 | 99.8 | 90.5 | 84.1 | 96.0 | 79.0 | 65.0 |

This shows the remarkable performance of specimen VII in the combined AWR/NSS and AWR/QUV tests.

Specimens VIII and IX are slightly inferior to VII in the AWR/NSS test combination and substantially inferior in the AWR/QUV combination, while still being at a high level, unknown before the implementation of the invention.

### EXAMPLE 4

This example describes a particular treatment of the magnetron-deposited (800 Pa/8 μbar) SiO₂ sublayers.

This treatment comprised:
(1) Five minutes, treatment in Ar (80 sccm, 19.98 Pa/150 mTorr), 200 W (35 V bias voltage) in order to reduce any residual roughness;
(2) Flash surface treatment: duration ≦60 s (=60 s in this example), C₂F₆, SF₆, O₂, H₂;
(3) Fluorosilane application by wiping.

Specimens X to XV are described below by the characteristics of their treatment step (2):
X: 26.66 Pa/200 mTorr, 230 W, 50 scam C₂F₆, 50 sccm O₂;
XI: as X, except 100 sccm C₂F₆;
XII: as X, except 70 sccm SF₆ and 30 sccm O₂;
XIII: 9.99 Pa/75 mTorr, 203 W, 100 sccm SF₆;
XIV: 7.99 Pa/60 mTorr, 230 W, 100 scam O₂; and
XV: 13.33 Pa/100 mTorr, 230 W, 75 scam H₂.

The amount of grafted fluorine [F] was determined by electron microprobe, and then an Opel friction resistance test was carried out. The results are given in Table 9 below.

TABLE 9

| | | | μ_{water} (° C.) | | |
|---|---|---|---|---|---|
| | Etched | Grafted | | Opel | Opel |
| | thickness | fluorine | | (5000 | (15 000 |
| Specimen | (nm) | (μg/cm²) | Initial | cycles) | cycles) |
| X | 10 | 0.9 | 109.3 | 102 | 93.9 |
| XI | <5 | 0.4 | 104.1 | 105.5 | 103.3 |
| XII | 16 | 0.8 | 110.6 | 103.7 | 93.6 |
| XIII | | 0.4 | 105 | 104.6 | 100 |
| XIV | <5 | 0.3 | 106.9 | 103 | 101.8 |
| XV | <5 | 0.4 | 111.9 | 103.9 | 103.3 |

These results show that the friction resistance is not directly correlated with the amount of grafted fluorine, or with the roughness of the sublayer (since the etched thicknesses do not exceed 16 nm, the increase in roughness generated by the etching process is in this case negligible). However, the fluorine grafting mode plays a role that depends on the surface treatment.

The invention has been described using the word “substrate”. It should be understood that this substrate may be a bare substrate, but it may also be a substrate already provided with functionalities other than the rain-repellent functionality, in particular thanks to layers, and, in certain cases, the sublayer according to the invention may then already form part of the layers that provide these other functionalities.

1. A substrate, at least one part of the surface of which has been rendered hydrophobic, having for this purpose a hydrophobic surface structure comprising an essentially mineral silicon-containing sublayer and an outer layer of hydrophobic agent grafted onto said sublayer, wherein said sublayer has received the outer layer of hydrophobic agent, said sublayer having a surface that was in an activated state before being brought into contact with said hydrophobic agent.

2. The substrate as claimed in claim 1, wherein the sublayer is a hard sublayer.

3. The substrate as claimed in claim 1, wherein it is formed by a plate, whether plane or with curved faces, of monolithic or laminated glass, of glass-ceramic or of a hard thermoplastic, such as polycarbonate.

4. The substrate as claimed in claim 3, wherein the sublayer of the hydrophobic coating forms part of the substrate, the latter being formed by a plate, whether plane or with curved faces, of monolithic or laminated glass or of glass-ceramic, the composition of which, at least on the surface, corresponds to that of the essentially mineral silicon-containing sublayer.

5. The substrate as claimed in claim 4, wherein the substrate is a glass dealkalized at least on its surface.

6. The substrate as claimed in claim 1, wherein said sublayer is formed by a compound chosen from SiOₓ, where x≦2, SiOC, SiON, SiOCN and Si₃N₄, it being possible for hydrogen to be combined in all proportions with SiOₓ, where x≦2, SiOC, SiON and SiOCN.

7. The substrate as claimed in claim 1, wherein the silicon-containing sublayer contains aluminum, in particular up to 8% by weight, or carbon, Ti, Zr, Zn and B.

8. The substrate as claimed in claim 1, wherein the silicon-containing sublayer when its surface is in the activated state has a thickness of between 20 nm and 250 nm, especially between 30 nm and 100 nm and in particular between 30 nm and 75 nm.

9. The substrate as claimed in claim 1, wherein the silicon-containing sublayer has, when its surface is in the activated state, an RMS roughness of between 0.1 nm and 40 nm, in particular between a few nm and 30 nm.

10. The substrate as claimed in claim 1, wherein the silicon-containing sublayer when its surface is in the activated state has an actual developed area at least 40% greater than the initial plane area.

11. The substrate as claimed in claim 1, wherein the silicon-containing sublayer when its surface is in the activated state has a hardness such that it does not delaminate after 100 revolutions, and preferably up to 200 revolutions, in the Taber test.

12. The substrate as claimed in claim 1, wherein the outer layer of hydrophobic agent is based on a hydrophobic agent chosen from:
(a) alkylsilanes of formula (I):
CH₃(CH₂)ₙSiRₘX₃₋ₘ (I)
in which:
n ranges from 0 to 30, more particularly from 0 to 18;
m=0, 1, 2 or 3;
R represents an optionally functionalized organic chain; and
X represents a hydrolyzable residue, such as an OR⁰ residue, where R⁰ represents hydrogen; or a linear, branched or cyclic, especially C₁-C₈, alkyl residue; or an aryl residue; or such as a halo, for example chloro, residue;
(b) compounds with grafted silicone chains;
(c) fluorosilanes, such as those of formula (II):
R¹-A-SiRₚ²X₃₋ₚ (II)
in which:
R¹ represents an especially C₁-C₉ monofluoroalkyl, oligofluoroalkyl or perfluoroalkyl residue; or a monoaryl, oligoaryl or perfluoroaryl residue;
A represents a hydrocarbon chain, optionally interrupted by a heteroatom such as O or S;
R² represents a linear, branched or cyclic, especially C₁-C₈, alkyl residue, or an aryl residue; X represents a hydrolyzable residue, such as an OR³ residue, where R³ represents hydrogen or a linear, branched or cyclic, especially C₁-C₈, alkyl residue; or an aryl residue; or such as a halo, for example chloro, residue; and
p=0, 1 or 2.

13. The substrate as claimed in claim 1, wherein the layer of hydrophobic agent has a thickness of between 1 and 100 nm, preferably between 2 and 50 nm.

14. The substrate as claimed in claim 1, wherein the layer of hydrophobic agent has a weight per unit area of grafted fluorine of between 0.1 μg/cm² and 3.5 μg/cm².

15. A process for manufacturing a substrate as defined in claim 1 comprising depositing a coating layer of hydrophobic agent, in at least one pass, on the surface of a silicon-containing mineral layer formed at least partly on the surface of the substrate, said deposition of the hydrophobic agent taking place while said surface is in the activated state.

16. The process as claimed in claim 15, wherein an activated surface of the silicon-containing mineral layer is obtained by depositing it under conditions in which its surface is obtained directly in the activated state.

17. The process as claimed in claim 15, wherein an activated surface of the silicon-containing mineral layer is obtained by carrying out an activation treatment in at least one pass.

18. The process as claimed in claim 15, wherein the hydrophobic agent is deposited within the shortest possible time, preferably between 1 second and 15 minutes, after the activated surface has been obtained.

19. The process as claimed in claim 17, wherein an activation treatment is carried out under conditions that do not go as far as etching, by the use of a plasma or an ionized gas, at reduced or atmospheric pressure, chosen from air, oxygen, nitrogen, argon, hydrogen, ammonia and mixtures thereof, or by the use of an ion beam.

20. The process as claimed in claim 17, wherein an activation treatment is carried out under conditions that allow a silicon-containing layer to be etched, by the use of a plasma of at least one fluorine-containing gas chosen from SF₆, CF₄, C₂F₆ and other fluorinated gases, where appropriate combined with oxygen, it being possible for the oxygen to represent up to 50% by volume of the etching plasma.

21. The process as claimed in claim 20, wherein the activation carried out under conditions that allow the silicon-containing layer to be etched by an activation treatment, which does not cause additional etching but does still modify the chemical nature and/or the electrostatic state of said layer, is monitored.

22. The process as claimed in claim 15, wherein the silicon-containing layer is deposited, cold, on the substrate by vacuum cathode sputtering, preferably magnetron sputtering and/or ion beam sputtering, or by low-pressure or atmospheric-pressure PECVD (plasma-enhanced chemical vapor deposition), or else deposited hot by pyrolysis.

23. The process as claimed in claim 22, wherein a layer of SiO₂ is deposited, as silicon-containing layer, by PECVD, using a mixture of an organic or nonorganic, silicon-containing precursor, such as SiH₄, hexamethyldisiloxane, tetraethoxysilane and tetramethyldisiloxane, and an oxidizer, the subsequent activation being carried out in the same chamber or in a separate chamber.

24. The process as claimed in claim 15, wherein the fluorosilane layer is deposited by wiping-on, evaporation or spraying of a solution containing the fluorosilane, or by dipping, spin-coating, flow-coating, etc., using a solution containing the fluorosilane.

25. The process as claimed in claim 15 for the manufacture of glazing having a hydrophobic coating, comprising depositing the sublayer on the glass on a glass manufacturing line using the “float” process while the glass is being supported by the bath of molten tin, or in a subsequent step, that is to say on leaving the bath of molten tin, in that the conversion operations are then carried out, such as bending, toughening and/or assembling, especially by lamination, in order to obtain plates of glass made up from one or more sheets coated with the sublayer on at least one face, in that the sublayer or sublayers supported by said plates are then activated and in that, finally, a functionalization by the hydrophobic agent of the sublayer or sublayers thus activated is carried out.

26. The process as claimed in claim 15 for the manufacture of glazing having a hydrophobic coating, wherein sheets of glass are manufactured by the float process, in that said glass sheets are then converted by operations such as bending, toughening and/or assembling, especially lamination, in order to obtain plates of glass made up from one or more sheets, in that the sublayer is then deposited on at least one face of the plates thus obtained, and in that the sublayer or sublayers are then activated, followed by the functionalization by the hydrophobic agent of the sublayer or sublayers thus activated.

27. The process as claimed in claim 15, wherein the sublayer is deposited on at least one face of glass sheets obtained upon leaving the float process, in that these sheets thus coated with the sublayer or sublayers are converted, limiting the techniques used to those that do not damage said sublayer(s), and in that the sublayer or sublayers are then activated, followed by the functionalization by the hydrophobic agent of said sublayer or sublayers thus activated.

28. A rain-repellent glazing comprising a substrate as defined in claim 1.

29. A glazing for the automotive, aviation, building, electrical household appliance and ophthalmic lens industries comprising the rain-repellent glazing of claim 28.
